(19) United States
(12) Patent Application Publication
(10) Pub. No.: US 2004/0207055 A1
(43) Pub. Date: Oct. 21, 2004

(54) Lead frame, semiconductor chip package, method for manufacturing semiconductor device, and semiconductor device

(76) Inventor: Yoshiro Iwasa, Matsumoto-shi (JP)

Correspondence Address: HARNESS, DICKEY & PIERCE, P.L.C., P.O. BOX 828, BLOOMFIELD HILLS, MI, 48303, US

(21) Appl. No.: 10/779,563

(22) Filed: Feb. 16, 2004

(30) Foreign Application Priority Data
Feb. 21, 2003 (JP) 2003-044360

(51) Int. Cl. H01L 21/44; H01L 23/495

(52) U.S. Cl. 257/676; 438/123

(57) ABSTRACT

A lead frame is provided that is capable of packaging semiconductor chips with different sizes. The lead frame has a frame-shaped land; a die pad for mounting the semiconductor chip; first to fourth supporters supporting the die pad so that the die pad is located in the center of the land; and first to fourth groups of lead members formed in first to fourth trapezoidal areas, the shorter bases of which face the center of the land and the longer bases of which face the sides of the land. The first to fourth groups of lead members have first ends and second ends, the first ends being fixed to the land, and the second ends being along the shorter bases or legs of the first to fourth trapezoidal areas. The second ends are parallel in each group.

### RELATED APPLICATIONS

The present application claims priority to Japanese Patent Application No. 2003-044360 filed Feb. 21, 2003 which is hereby expressly incorporated by reference herein in its entirety.

### BACKGROUND OF THE INVENTION

1. Technical Field of the Invention

The present invention relates to a lead frame, a semiconductor chip package, a method for manufacturing a semiconductor device, and a semiconductor device.

2. Description of the Related Art

A known semiconductor chip package will be described with reference to FIG. 18. As shown in FIG. 18, the known semiconductor chip package 101 has a substrate 102 for mounting a semiconductor chip.

The substrate 102 has first to fourth trapezoidal areas, the shorter bases of which face the center of the substrate 102 and the longer bases of which face the sides of the substrate 102. In the first to fourth trapezoidal areas on one surface of the substrate 102, first to fourth groups of lead members 103 to 106 are formed. The first to fourth groups of lead members 103 to 106 are formed radially from the center of the substrate 102.

In the center of the substrate 102, a semiconductor chip 111 is disposed. On four sides of the semiconductor chip 111, first to fourth groups of bonding pads are formed. The first to fourth groups of lead members 103 to 106 and the first to fourth groups of bonding pads are connected with first to fourth groups of wires 107 to 110.

Such a known semiconductor chip package is designed and manufactured according to the size of a semiconductor chip to be packaged and it cannot be used for packaging semiconductor chips with different sizes.

Now, a lead frame for mounting a semiconductor chip is known. For example, see Japanese Unexamined Patent Application Publication No. 2000-49272 (Page 1, FIG. 1).

The lead frame disclosed in Japanese Unexamined Patent Application Publication No. 2000-49272 has improved reflow crack resistance, thereby being capable of mounting a semiconductor chip satisfactorily. However, it is not capable of mounting semiconductor chips with different sizes.

Accordingly, it is an object of the present invention to provide a lead frame that is capable of packaging semiconductor chips with different sizes. It is another object of the present invention to provide a package that is capable of packaging semiconductor chips with different sizes.

It is still another object of the present invention to provide a method for manufacturing a semiconductor device including such a lead frame or a package. It is yet another object of the present invention to provide a semiconductor device manufactured by such a method.

### SUMMARY

To address these problems, a lead frame for packaging a semiconductor chip according to the present invention has a frame-shaped land; a die pad for mounting the semiconductor chip; first to fourth supporters formed in the four corners of the land and supporting the die pad so that the die pad is located inside the land; and first to fourth groups of lead members having first ends and second ends, the first ends being fixed to the land, and the second ends being parallel in each group.

The first to fourth groups of lead members are preferably formed in first to fourth trapezoidal areas, the shorter bases of which face the center of the land and the longer bases of which face the sides of the land, and the second ends of the first to fourth groups of lead members are preferably along the shorter bases or legs of the first to fourth trapezoidal areas.

A method for manufacturing a semiconductor device including a lead frame according to the first aspect of the present invention has the steps of (a) cutting the first to fourth groups of lead members according to the size of the semiconductor chip to be packaged; (b) mounting the semiconductor chip on the die pad; (c) bonding the first to fourth groups of lead members and the semiconductor chip with a plurality of wires; (d) fitting terminals to the land, for connecting the first to fourth groups of lead members to an external circuit; and (e) encapsulating the lead frame and the semiconductor chip.

A package for packaging a semiconductor chip according to the present invention has a substrate for mounting the semiconductor chip, the substrate having a first surface and a second surface; first to fourth groups of terminals formed on the first surface of the substrate; first to fourth groups of wiring patterns formed in the substrate and connected to the first to fourth groups of terminals; and fifth to eighth groups of wiring patterns formed on the second surface of the substrate and having first ends and second ends, the first ends being connected to the first to fourth groups of wiring patterns, and the second ends being parallel in each group.

The fifth to eighth groups of wiring patterns are preferably formed in first to fourth trapezoidal areas, the shorter bases of which face the center of the substrate and the longer bases of which face the sides of the substrate, and the second ends of the fifth to eighth groups of wiring patterns are preferably along the shorter bases or legs of the first to fourth trapezoidal areas.

A method for manufacturing a semiconductor device including a package according to the second aspect of the present invention has the steps of (a) cutting the fifth to eighth groups of wiring patterns according to the size of the semiconductor chip to be packaged; (b) mounting the semiconductor chip on the substrate; (c) bonding the fifth to eighth groups of wiring patterns and the semiconductor chip with a plurality of wires; and (d) covering the second surface of the package and the semiconductor chip.

A semiconductor device according to the present invention is manufactured by a method according to the first or second aspect.

The present invention makes it possible to package semiconductor chips with different sizes.

### BRIEF DESCRIPTION OF THE DRAWINGS

FIG. 1 shows a lead frame according to an embodiment of the present invention.

FIG. 2 is a sectional view taken along line II-II′ of FIG. 1.

FIG. 3 is a sectional view taken along line III-III′ of FIG. 1.

FIG. 4 shows the lead frame 1 on which a semiconductor chip is mounted.

FIG. 5 is a sectional view taken along line V-V′ of FIG. 4.

FIG. 6 shows the lead frame 1 on which another semiconductor chip is mounted.

FIG. 7 is a sectional view taken along line VII-VII′ of FIG. 6.

FIG. 8 shows the lead frame 1 on which another semiconductor chip is mounted.

FIG. 9 is a sectional view taken along line IX-IX′ of FIG. 8.

FIG. 10 shows a package according to another embodiment of the present invention.

FIG. 11 is a sectional view taken along line XI-XI′ of FIG. 10.

FIG. 12 shows the package 51 on which a semiconductor chip is mounted.

FIG. 13 is a sectional view taken along line XIII-XIII′ of FIG. 12.

FIG. 14 shows the package 51 on which another semiconductor chip is mounted.

FIG. 15 is a sectional view taken along line XV-XV′ of FIG. 14.

FIG. 16 shows the package 51 on which another semiconductor chip is mounted.

FIG. 17 is a sectional view taken along line XVII-XVII′ of FIG. 16.

FIG. 18 shows a known semiconductor chip package.

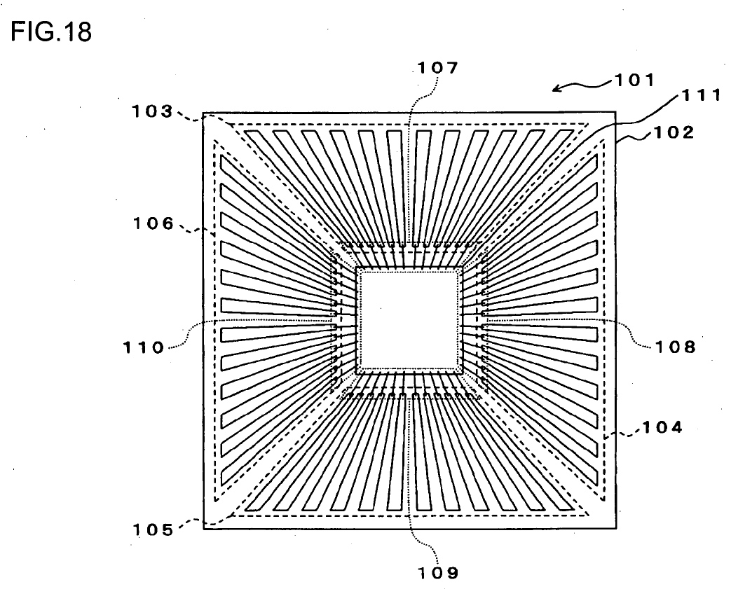

### DETAILED DESCRIPTION

Embodiments of the present invention will now be described with reference to the drawings.

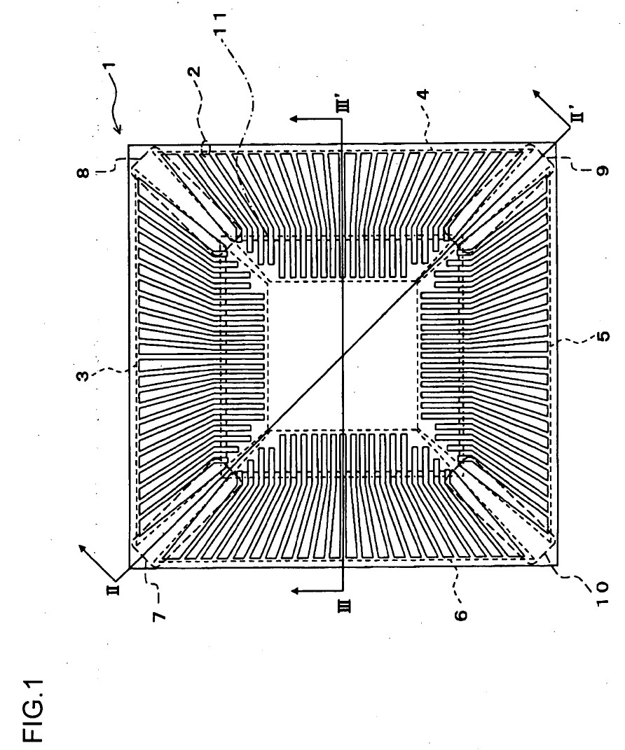

FIG. 1 shows a lead frame according to an embodiment of the present invention. As shown in FIG. 1, the lead frame 1 has a land 2, which is a rectangular frame. Inside the land 2, first to fourth trapezoidal areas are provided, the shorter bases of which face the center of the land 2 and the longer bases of which face the sides of the land 2. In the first to fourth areas, first to fourth groups 3 to 6 of lead members are formed. The first to fourth groups 3 to 6 of lead members have first ends and second ends, the first ends being fixed to the land 2, and the second ends being along the shorter bases or legs of the first to fourth trapezoidal areas. The lead members of each group 3, 4, 5, or 6 are parallel at the second ends.

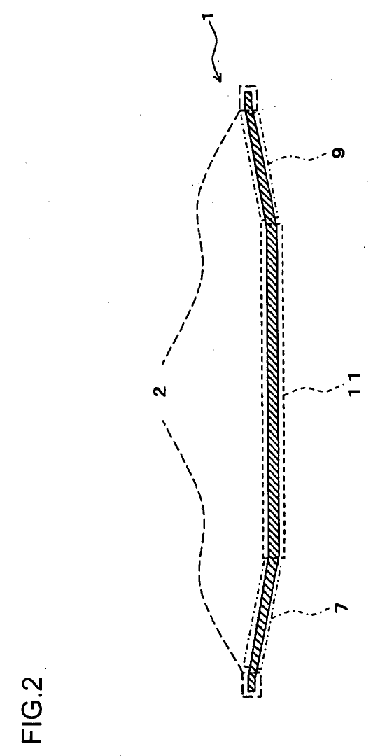

Supporters 7 to 10 reside in the four corners of the land 2. A die pad 11 for mounting a semiconductor chip is supported by these supporters 7 to 10. FIG. 2 is a sectional view of the lead frame 1 taken along line II-II′ of FIG. 1. FIG. 2 shows two supporters 7 and 9 of the supporters 7 to 10 supporting the die pad 11.

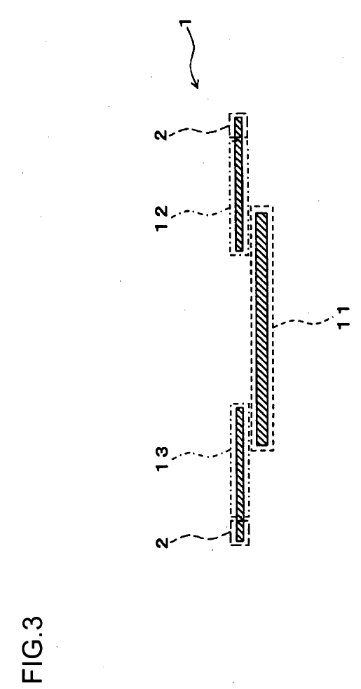

FIG. 3 is a sectional view of the lead frame 1 taken along line III-III′ of FIG. 1. FIG. 3 shows a lead member 12, which belongs to the second group 4 of lead members, and another lead member 13, which belongs to the fourth group 6 of lead members.

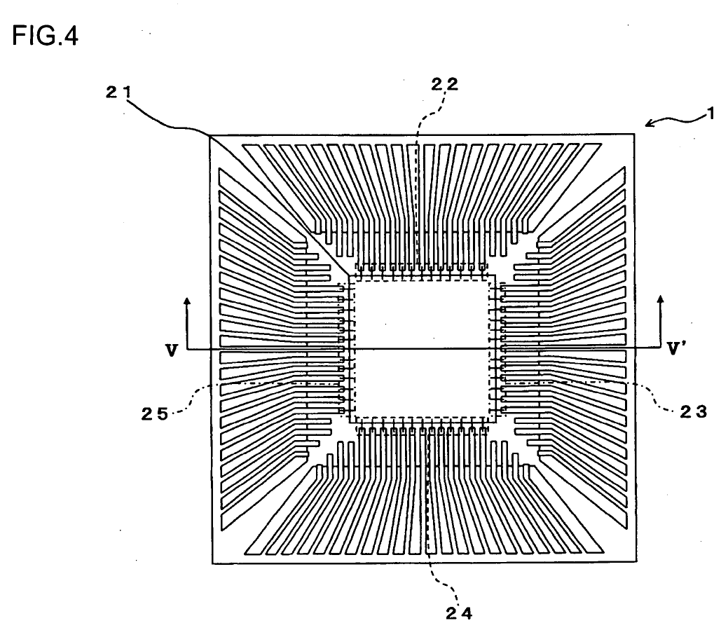

FIG. 4 shows the lead frame 1 on which a semiconductor chip 21 is mounted, the semiconductor chip 21 being the smallest one among semiconductor chips with different sizes that can be packaged with the lead frame 1. As shown in FIG. 4, the semiconductor chip 21 is disposed on the die pad 11 of the lead frame 1.

Some of the lead members in the first to fourth groups 3 to 6, that is, the lead members whose second ends are along the shorter bases of the first to fourth trapezoidal areas, are connected to first to fourth groups of bonding pads formed on four sides of the semiconductor chip 21 with first to fourth groups of wires 22 to 25.

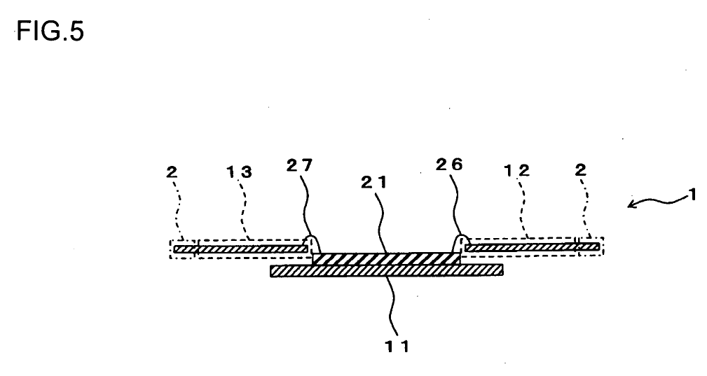

FIG. 5 is a sectional view of the lead frame 1 and the semiconductor chip 21 taken along line V-V′ of FIG. 4. In FIG. 5, a wire 26, which belongs to the second group 23 of wires, connects a lead member 12 to the semiconductor chip 21, and another wire 27, which belongs to the fourth group 25 of wires, connects another lead member 13 to the semiconductor chip 21.

Then, terminals are fitted to the land 2, for communicating a signal sent and received between an external circuit and the semiconductor chip 21. In addition, the lead frame 1 and the semiconductor chip 21 are encapsulated in plastic. A semiconductor device is thus manufactured.

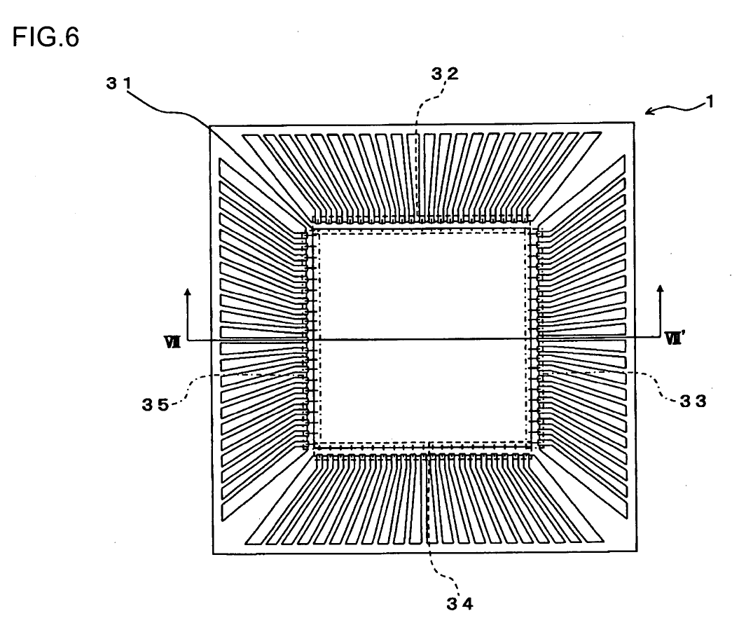

FIG. 6 shows the lead frame 1 on which a semiconductor chip 31 is mounted, the semiconductor chip 31 being the largest one among semiconductor chips with different sizes that can be packaged with the lead frame 1. As shown in FIG. 6, the semiconductor chip 31 is disposed on the die pad 11 of the lead frame 1.

In FIG. 6, all lead members in each group 3, 4, 5, or 6 are cut so as not to overlap the semiconductor chip 31, except for the lead members at both ends of the group. The first to fourth groups 3 to 6 of lead members are connected to first to fourth groups of bonding pads formed on four sides of the semiconductor chip 31 with first to fourth groups of wires 32 to 35.

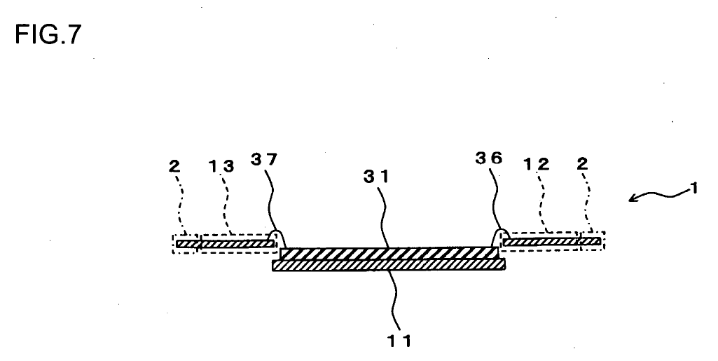

FIG. 7 is a sectional view of the lead frame 1 and the semiconductor chip 31 taken along line VII-VII′ of FIG. 6. In FIG. 7, a wire 36, which belongs to the second group of wires 33, connects a lead member 12 to the semiconductor chip 31, and another wire 37, which belongs to the fourth group of wires 35, connects another lead member 13 to the semiconductor chip 31.

Then, terminals are fitted to the land 2, for connecting to an external circuit. In addition, the lead frame 1 and the semiconductor chip 31 are encapsulated in plastic. A semiconductor device is thus manufactured.

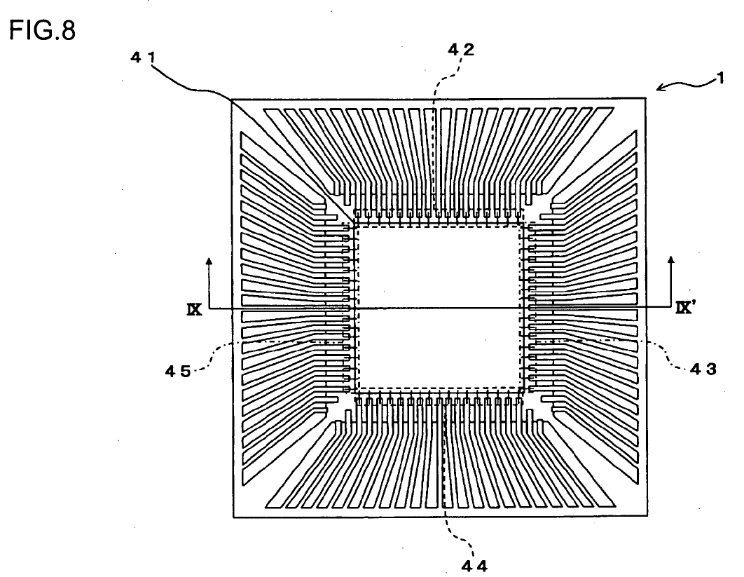

FIG. 8 shows the lead frame 1 on which a semiconductor chip 41 is mounted, the semiconductor chip 41 being larger than the smallest semiconductor chip 21 shown in FIG. 4 and smaller than the largest semiconductor chip 31, shown in FIG. 6. As shown in FIG. 8, the semiconductor chip 41 is disposed on the die pad 11 of the lead frame 1.

In FIG. 8, the lead members in the inner portion of each group 3, 4, 5, or 6 are cut so as not to overlap the semiconductor chip 41. These lead members are connected to first to fourth groups of bonding pads formed on four sides of the semiconductor chip 41 with first to fourth groups of wires 42 to 45.

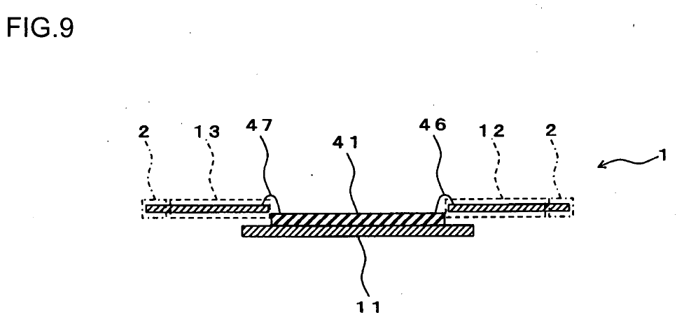

FIG. 9 is a sectional view of the lead frame 1 and the semiconductor chip 41 taken along line IX-IX′ of FIG. 8. In FIG. 9, a wire 46, which belongs to the second group 43 of wires, connects a lead member 12 to the semiconductor chip 41, and another wire 47, which belongs to the fourth group 45 of wires, connects another lead member 13 to the semiconductor chip 41.

Then, terminals are fitted to the land 2, for connecting to an external circuit. In addition, the lead frame 1 and the semiconductor chip 41 are encapsulated in plastic. A semiconductor device is thus manufactured.

As described above, this lead frame 1 is capable of packaging semiconductor chips with various sizes.

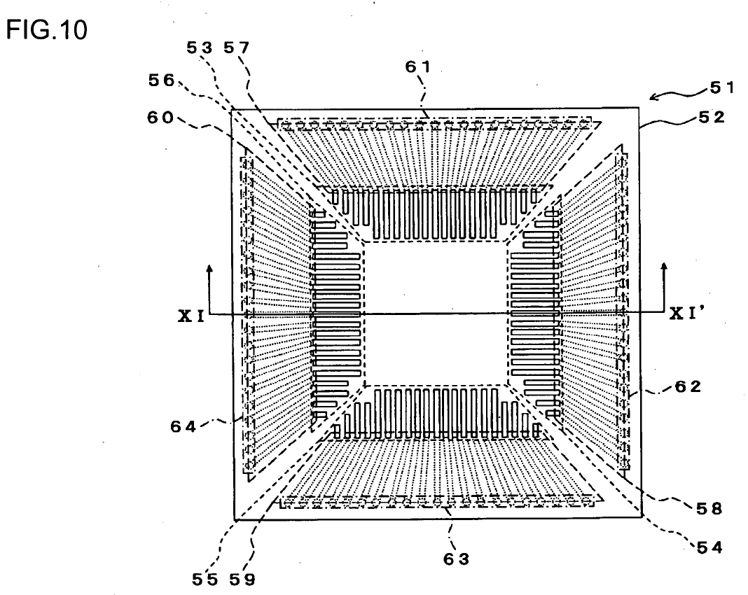

Another embodiment of the present invention will now be described. FIG. 10 shows a semiconductor chip package according to another embodiment of the present invention. As shown in FIG. 10, the package 51 has a substrate 52 for mounting a semiconductor chip.

The substrate 52 has first to fourth trapezoidal areas, the shorter bases of which face the center of the substrate 52 and the longer bases of which face the sides of the substrate 52. In the first to fourth trapezoidal areas on one surface of the substrate 52, first to fourth groups 53 to 56 of upper layer wiring patterns are formed.

Concerning the first to fourth groups 53 to 56 of upper layer wiring patterns, the ends that face the center of the substrate 52 are along the shorter bases or legs of the first to fourth trapezoidal areas. The upper layer wiring patterns of each group 53, 54, 55, or 56 are parallel at the ends facing the center of the substrate 52.

Outside of the first to fourth trapezoidal areas, the substrate 52 has fifth to eighth trapezoidal areas, the shorter bases of which face the center of the substrate 52 and the longer bases of which face the sides of the substrate 52. In the fifth to eighth trapezoidal areas in the substrate 52, first to fourth groups 57 to 60 of middle layer wiring patterns are formed. On the other surface of the substrate 52, first to fourth groups 61 to 64 of terminals are formed along the longer bases of the fifth to eighth trapezoidal areas. The first to fourth groups 57 to 60 of middle layer wiring patterns are connected to the first to fourth groups 53 to 56 of upper layer wiring patterns at one ends via through-holes, and are connected with the first to fourth groups 61 to 64 of terminals at the other ends via other through-holes.

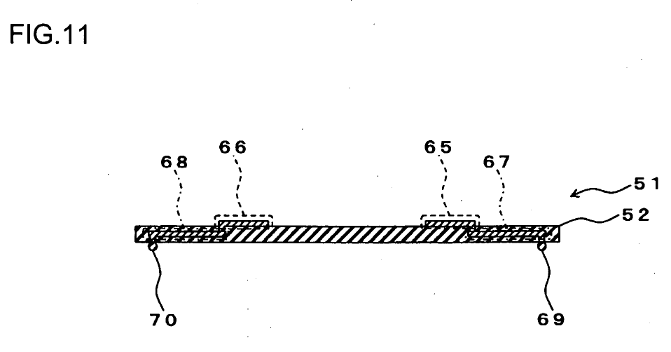

FIG. 11 is a sectional view of the substrate 52 taken along line XI-XI′ of FIG. 10. FIG. 11 shows an upper layer wiring pattern 65, which belongs to the second group 54 of upper layer wiring patterns; another upper layer wiring pattern 66, which belongs to the fourth group 56 of upper layer wiring patterns; a middle layer wiring pattern 67, which belongs to the second group 58 of middle layer wiring patterns; another middle layer wiring pattern 68, which belongs to the fourth group 60 of middle layer wiring patterns; a terminal 69, which belongs to the second group 62 of terminals; and another terminal 70, which belongs to the fourth group 64 of terminals.

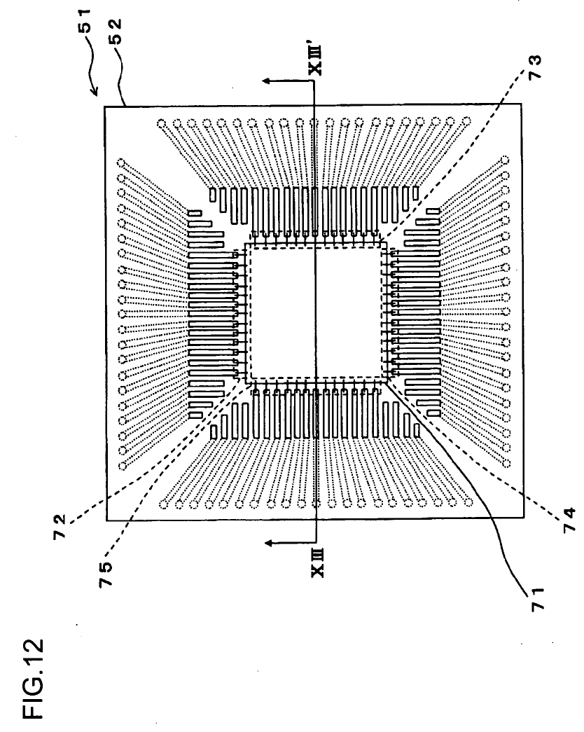

FIG. 12 shows the package 51 on which a semiconductor chip 71 is mounted, the semiconductor chip 71 being the smallest one among semiconductor chips with different sizes that can be packaged with the package 51. As shown in FIG. 12, the semiconductor chip 71 is disposed in the center of the substrate 52.

Some of the upper layer wiring patterns in the first to fourth groups 53 to 56, that is, the upper layer wiring patterns whose one ends are along the shorter bases of the first to fourth trapezoidal areas, are connected to first to fourth groups of bonding pads formed on four sides of the semiconductor chip 71 with first to fourth groups 72 to 75 of wires.

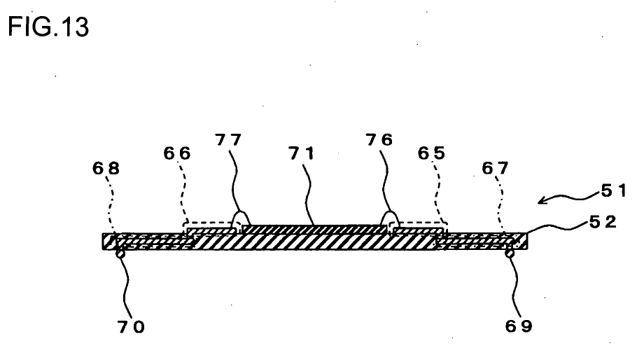

FIG. 13 is a sectional view of the package 51 and the semiconductor chip 71 taken along line XIII-XIII′ of FIG. 12. In FIG. 13, a wire 76, which belongs to the second group 73 of wires, connects an upper layer wiring pattern 65 to the semiconductor chip 71, and another wire 77, which belongs to the fourth group of wires 75, connects another upper layer wiring pattern 66 to the semiconductor chip 71.

Then, the upper surface of the package 51 and the semiconductor chip 71 are covered with plastic. A semiconductor device is thus manufactured.

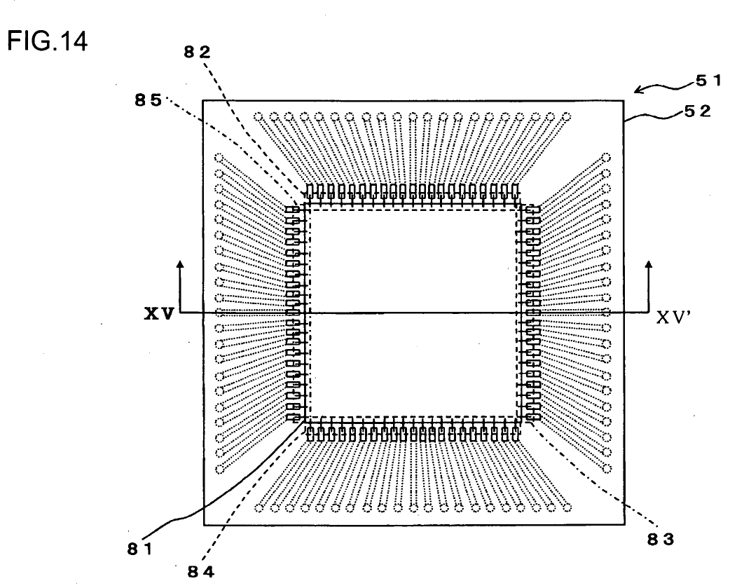

FIG. 14 shows the package 51 on which a semiconductor chip 81 is mounted, the semiconductor chip 81 being the largest one among semiconductor chips with different sizes that can be packaged with the package 51. As shown in FIG. 14, the semiconductor chip 81 is disposed in the center of the substrate 52.

In FIG. 14, all upper layer wiring patterns in each group 53, 54, 55, or 56 are cut so as not to overlap the semiconductor chip 81, except for the upper layer wiring patterns at both ends of the group. The first to fourth groups 53 to 56 of upper layer wiring patterns are connected to first to fourth groups of bonding pads formed on four sides of the semiconductor chip 81 with first to fourth groups 82 to 85 of wires.

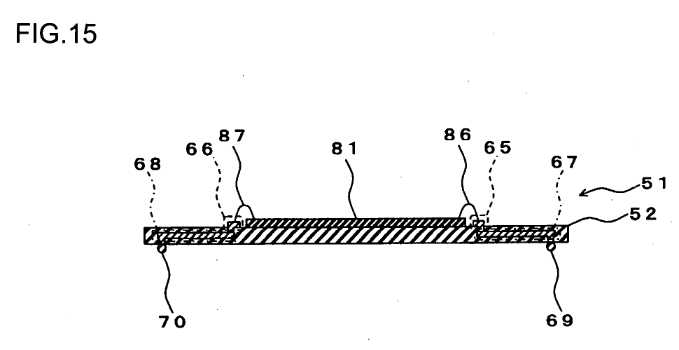

FIG. 15 is a sectional view of the package 51 and the semiconductor chip 81 taken along line XV-XV′ of FIG. 14. In FIG. 15, a wire 86, which belongs to the second group 83 of wires, connects an upper layer wiring pattern 65 to the semiconductor chip 81, and another wire 87, which belongs to the fourth group 85 of wires, connects another upper layer wiring pattern 66 to the semiconductor chip 81.

Then, the upper surface of the package 51 and the semiconductor chip 81 are covered with plastic. A semiconductor device is thus manufactured.

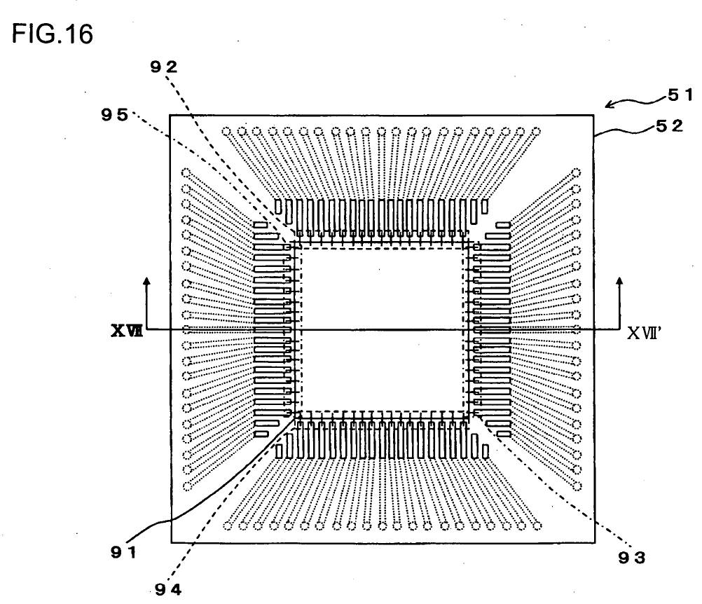

FIG. 16 shows the package 51 on which a semiconductor chip 91 is mounted, the semiconductor chip 91 being larger than the smallest semiconductor chip 71 shown in FIG. 12 and smaller than the largest semiconductor chip 81 shown in FIG. 14. As shown in FIG. 16, the semiconductor chip 91 is disposed in the center of the substrate 52.

In FIG. 16, the upper layer wiring patterns in the inner portion of each group 53, 54, 55, or 56 are cut so as not to overlap the semiconductor chip 91. These upper layer wiring patterns are connected to first to fourth groups of bonding pads formed on four sides of the semiconductor chip 91 with first to fourth groups 92 to 95 of wires.

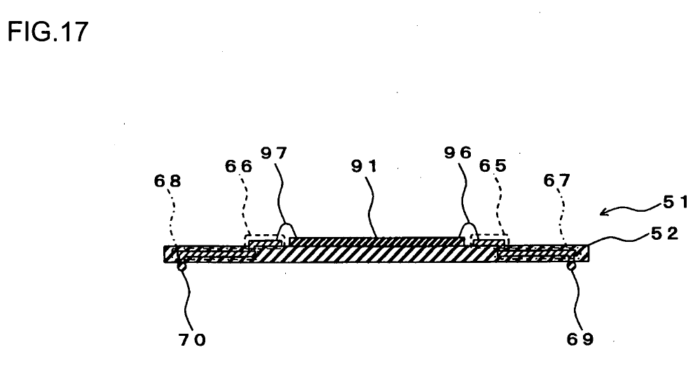

FIG. 17 is a sectional view of the package 51 and the semiconductor chip 91 taken along line XVII-XVII′ of FIG. 16. In FIG. 17, a wire 96, which belongs to the second group 93 of wires, connects an upper layer wiring pattern 65 to the semiconductor chip 91, and another wire 97, which belongs to the fourth group of wires 95, connects another upper layer wiring pattern 66 to the semiconductor chip 91.

Then, the upper surface of the package 51 and the semiconductor chip 91 are covered with plastic. A semiconductor device is thus manufactured.

As described above, this package 51 is capable of packaging semiconductor chips with various sizes.

What is claimed is:

1. A lead frame for packaging a semiconductor chip, the lead frame comprising:
a frame-shaped land;
a die pad for mounting the semiconductor chip;
first to fourth support portions formed in four corners of the land and supporting the die pad so that the die pad is located inside the land; and
first to fourth groups of lead members having first ends and second ends, the first ends being fixed to the land, and the second ends being parallel in each group.

2. A lead frame according to claim 1, wherein the first to fourth groups of lead members are formed in first to fourth trapezoidal areas, the shorter bases of which face a center of the land and the longer bases of which face sides of the land, and the second ends of the first to fourth groups of lead members are along the shorter bases of the first to fourth trapezoidal areas.

3. A method for manufacturing a semiconductor device including a lead frame having a frame-shaped land; a die pad for mounting the semiconductor chip; first to fourth support portions formed in four corners of the land and supporting the die pad so that the die pad is located inside the land; and first to fourth groups of lead members having first ends and second ends, the first ends being fixed to the land, and the second ends being parallel in each group, the method comprising the steps of:
(a) cutting the first to fourth groups of lead members according to the size of the semiconductor chip to be packaged;
(b) mounting the semiconductor chip on the die pad;
(c) bonding the first to fourth groups of lead members and the semiconductor chip with a plurality of wires;
(d) fitting terminals to the land, for connecting the first to fourth groups of lead members to an external circuit; and
(e) encapsulating the lead frame and the semiconductor chip.

4. A package for packaging a semiconductor chip, the package comprising:
a substrate for mounting the semiconductor chip, the substrate having a first surface and a second surface;
first to fourth groups of terminals formed on the first surface of the substrate;
first to fourth groups of wiring patterns formed on the substrate and connected to the first to fourth groups of terminals; and
fifth to eighth groups of wiring patterns formed on the second surface of the substrate and having first ends and second ends, the first ends being connected to the first to fourth groups of wiring patterns, and the second ends being parallel in each group.

5. A package according to claim 4, wherein the fifth to eighth groups of wiring patterns are formed in first to fourth trapezoidal areas, the shorter bases of which face a center of the substrate and the longer bases of which face sides of the substrate, and the second ends of the fifth to eighth groups of wiring patterns are along the shorter bases of the first to fourth trapezoidal areas.

6. A method for manufacturing a semiconductor device including a package having a substrate for mounting the semiconductor chip, the substrate having a first surface and a second surface; first to fourth groups of terminals formed on the first surface of the substrate; first to fourth groups of wiring patterns formed on the substrate and connected to the first to fourth groups of terminals; and fifth to eighth groups of wiring patterns formed on the second surface of the substrate and having first ends and second ends, the first ends being connected to the first to fourth groups of wiring patterns, and the second ends being parallel in each group, the method comprising the steps of:
(a) cutting the fifth to eighth groups of wiring patterns according to the size of the semiconductor chip to be packaged;
(b) mounting the semiconductor chip on the substrate;
(c) bonding the fifth to eighth groups of wiring patterns and the semiconductor chip with a plurality of wires; and
(d) encapsulating the second surface of the package and the semiconductor chip.
